(19) United States
(12) Patent Application Publication
(10) Pub. No.: US 2015/0137230 A1
(43) Pub. Date: May 21, 2015

(54) LATERALLY DIFFUSED METAL OXIDE SEMICONDUCTOR AND MANUFACTURING METHOD THEREOF

(71) Applicant: UNITED MICROELECTRONICS CORP., HSINCHU (TW)

(72) Inventor: Chien-Nan Liao, Taichung City (TW)

(73) Assignee: UNITED MICROELECTRONICS CORP., HSINCHU (TW)

(21) Appl. No.: 14/084,770

(22) Filed: Nov. 20, 2013

(51) Int. Cl. H01L 29/78; H01L 21/28; H01L 29/66; H01L 29/40

(52) U.S. Cl. CPC H01L 29/7816; H01L 29/40; H01L 21/28008; H01L 29/66681
USPC 257/343; 438/286

(57) ABSTRACT

A laterally diffused metal oxide semiconductor (LDMOS) and a manufacturing method thereof are provided. The LDMOS includes a substrate, a gate, a first well and a shallow trench isolation (STI). The gate is disposed above the substrate. The gate has a first gate region having a first dopant type and a second gate region having a second dopant type. The first well is disposed in the substrate. The STI is contacted with the first well and partially overlaps with the gate.

### BACKGROUND

1. Technical Field

The disclosure relates in general to a semiconductor device and a manufacturing method thereof, and more particularly to a laterally diffused metal oxide semiconductor (LDMOS) and a manufacturing method thereof.

2. Description of the Related Art

With the development of the power semiconductor technology and system integration technology, research on power devices has drawn more and more attentions. To meet market requirements regarding the size, weight, price, efficiency, performance and reliability of the power semiconductor, new technologies have been applied to a laterally diffused metal oxide semiconductor (LDMOS).

It is for this reason, the LDMOS and its production processes have improved continuously, and various derivative structures of LDMOS are emerging in an endless stream. Therefore, according to requirements in practical applications, it is necessary to provide a kind of LDMOS which has compact structure, low on-resistance, and can withstand high current and high voltage.

### SUMMARY

The disclosure is directed to a laterally diffused metal oxide semiconductor (LDMOS) and a manufacturing method thereof. A gate of the LDMOS has two regions having different dopant types, such that the on-resistance (Ron) of the LDMOS can be improved.

According to a first aspect of the present disclosure, a laterally diffused metal oxide semiconductor (LDMOS) is provided. The LDMOS includes a substrate, a gate, a first well and a shallow trench isolation (STI). The gate is disposed above the substrate. The gate has a first gate region having a first dopant type and a second gate region having a second dopant type. The first well is disposed in the substrate. The STI is contacted with the first well and partially overlaps with the gate.

According to a second aspect of the present disclosure, a manufacturing method of a laterally diffused metal oxide semiconductor (LDMOS) is provided. The manufacturing method of the LDMOS includes the following steps. A substrate is provided. A first well in the substrate is formed. A shallow trench isolation (STI) contacted with the first well is formed. A gate is formed above the substrate. A first gate region having a first dopant type in the gate is formed. A second gate region having a second dopant type in the gate is formed.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 schematically shows a laterally diffused metal oxide semiconductor (LDMOS) according to a first embodiment.

FIG. 2 shows a top view of the LDMOS of FIG. 1.

FIGS. 3A to 3E show a manufacturing method of the LDMOS of FIG. 1.

FIG. 4 shows a LDMOS according to a second embodiment.

FIG. 5 shows a LDMOS according to a third embodiment.

### DETAILED DESCRIPTION

Preferred embodiments are disclosed below for elaborating the invention. A gate of the LDMOS has two regions having different dopant types, such that the on-resistance (Ron) of the LDMOS can be improved.

The following embodiments are for the purpose of elaboration only, not for limiting the scope of protection of the invention. Besides, secondary elements are omitted in the following embodiments to highlight the technical features of the invention.

### First Embodiment

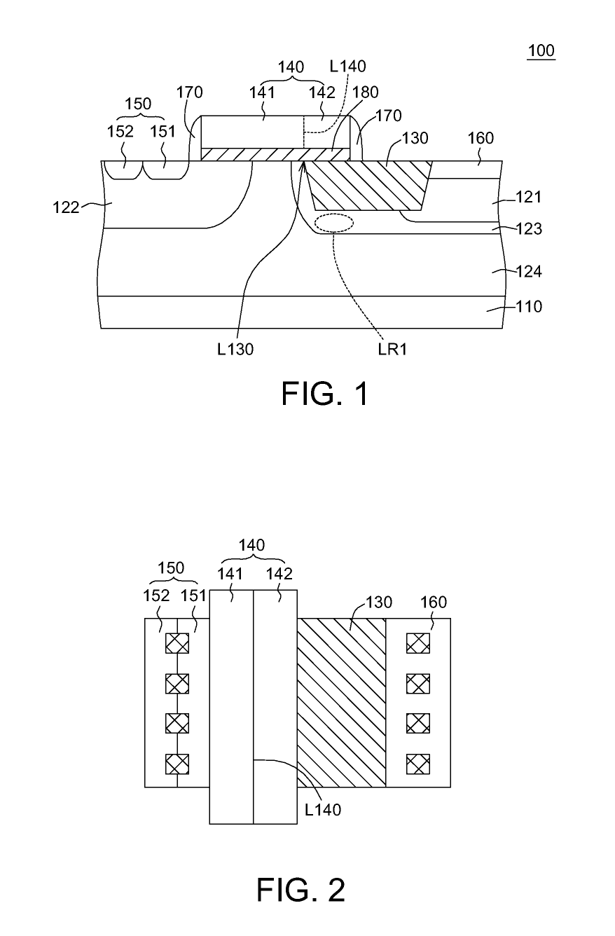

Please refer to FIG. 1, which schematically shows a laterally diffused metal oxide semiconductor (LDMOS) 100 according to a first embodiment. The LDMOS 100 includes a substrate 110, a first well 121, a second well 122, a deep field 123, a deep well 124, a shallow trench isolation (STI) 130, a gate 140, a source 150, a drain 160, a lateral insulating layer 170 and a gate oxide layer 180. In one embodiment, the LDMOS 100 can be used in microwave/RF power amplifiers or power amplifiers for base-stations where the requirement is for high output power with a corresponding drain to source breakdown voltage usually above 60 volts, but have low maximum power gain frequency compared to other devices such as GaAs FETs.

The substrate 110 can be a silicon (Si) substrate, a germanium (Ge) substrate, a gallium arsenide (GaAs) substrate, a sapphire substrate, a quartz substrate, a ceramic substrate, a graphene substrate or a silicon on insulator (SOI).

The deep well 124 is formed in the substrate 110. The deep field 123 is formed in the deep well 124. The first well 121 and the second well 122 are formed in the deep field 123 and the deep well 124 respectively. In the present embodiment, the second well 122 is spaced apart from the first well 121 and the deep field 123. The depth of the deep well 124 is larger than that of the deep field 123. The depth of the deep field 123 is larger than that of the first well 121.

The first well 121, the second well 122, the deep field 123 and the deep well 124 are formed by doping. For example, the first well 121 has a first dopant type, the second well 122 has a second dopant type, the deep field 123 has the first dopant type, and the deep well 124 has the first dopant type. The first dopant type and the second dopant type can be N type and P type respectively. The doping concentration of the deep field 123 is higher than that of the deep well 124. The doping concentration of the first well 121 is higher than that of the deep field 123.

The STI 130 is disposed in the deep field 123 and contacted with the first well 121. The STI 130 can be formed by etching a pattern of trenches in the substrate 110, depositing one or more dielectric materials (such as silicon dioxide) to fill the trenches, and removing the excess dielectric materials using a technique such as chemical-mechanical planarization.

The source 150 and the drain 160 are disposed in the second well 122 and the first well 121 respectively. The source 150 has a first source region 151 and a second source region 152. The source 150 and the drain 160 are spaced by the STI 130. The source 150 and the drain 160 can be formed by heavily doping. For example, the first source region 151 has the first dopant type, the second source region 152 has the second dopant type, and the drain 160 has the first dopant type. The first dopant type and the second dopant type can be N type and P type respectively.

The gate 140 is formed above the substrate 110 and located between the source 150 and the drain 160. The lateral insulating layer 170 is located at the lateral wall of the gate 140, and the gate oxide layer 180 is located between the gate 140 and the substrate 110. The gate 140 is partially overlapped with the STI 130. While the gate 140 is applied a suitable voltage, a channel will be formed between the source 150 and the drain 160 to switch on the LDMOS 100.

In the present embodiment, the gate 140 has a first gate region 141 and a second gate region 142. The first gate region 141 is located near the source 150, and the second gate region 142 is located near the drain 160. The first gate region 141 and the second gate region 142 are formed by doping. For example, the first gate region 141 has the first dopant type and the second gate region 142 has the second dopant type.

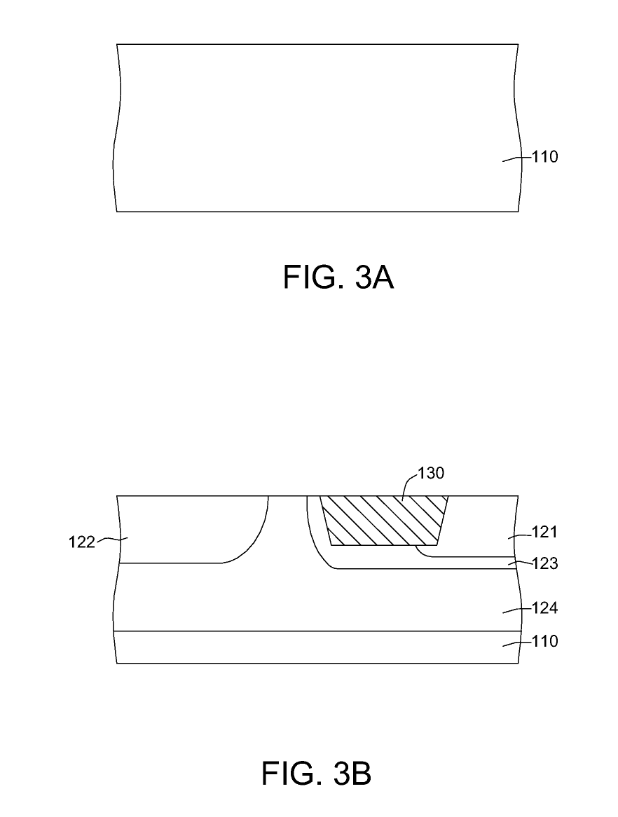

Please referring to FIG. 2, a top view of the LDMOS 100 of FIG. 1 is shown. In the present embodiment, the first gate region 141 and the second gate region 142 fully occupy the gate 140. The second gate region 142 is fully overlapped with the STI 130, and the first gate region 141 is located at an outside of the STI 130. Moreover, a border L140 between the first gate region 141 and the second gate region 142 is located at an edge L130 (shown in FIG. 1) of the STI 130. In the present embodiment, the border L140 is substantially a straight line.

The second gate region 142 having the second dopant type can induce a low resistance region LR1 located below the second gate region 142. The low resistance region LR1 can lower the resistance of the current path for improving the on-resistance (Ron) of the LDMOS 100. Please referring to Table I, which shows a comparison between a LDMOS whose gate is not doped any dopants and the LDMOS 100 of the present embodiment. The breakdown voltage of the LDMOS 100 can be kept at 40 V, which is substantially equal to the breakdown voltage of the LDMOS whose gate is not doped any dopants. Furthermore, the Ron of the LDMOS 100 can be reduced to 30.22 mohm*mm² which is 91.1% of the Ron of the LDMOS whose gate is not doped any dopants. That is to say, the low resistance region LR1 can lower the Ron without effecting the breakdown voltage.

TABLE I

| | Breakdown voltage (V) | Ron, sp (mohm*mm²) |
|---|---|---|
| LDMOS whose gate is | 40.4 | 33.18 |
| not doped any dopants | | |
| LDMOS 100 | 40 | 30.22 |

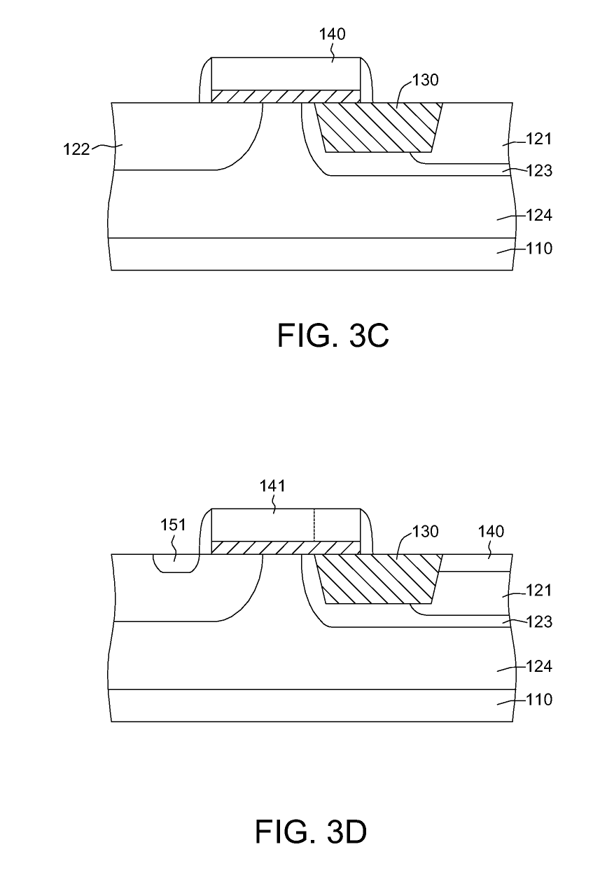

Please referring to FIGS. 3A to 3E, a manufacturing method of the LDMOS 100 of FIG. 1 is shown. In FIG. 3A, the substrate 110 is provided.

In FIG. 3B, the deep well 124, the deep field 123, the first well 121, the second well 122 and the STI 130 are formed in the substrate 110. The sequence of forming the deep well 124, the deep field 123, the first well 121, the second well 122 and the STI 130 is not limited here.

In FIG. 3C, the gate 140 is formed above the substrate 110. At this step, the gate 140 is not doped any dopants yet.

In FIG. 3D, the drain 140, the first source region 151 and the first gate region 141 are formed in the first well 121, the second well 122 and the gate 140 respectively. Because the doping concentration of the first gate region 141 can be identical to that of the drain 140 and the first source region 151, the steps of forming the first gate region 141, forming the drain 140 and forming the first source region 151 can be performed at the same time without any additional mask.

In FIG. 3E, the second source region 152 and the second gate region 142 are formed in the second well 122 and the gate respectively. Because the doping concentration of the second gate region 142 can be identical to that of the second source region 152, the steps of forming the second gate region 142 and forming the second source region 152 can be performed at the same time without any additional mask.

### Second Embodiment

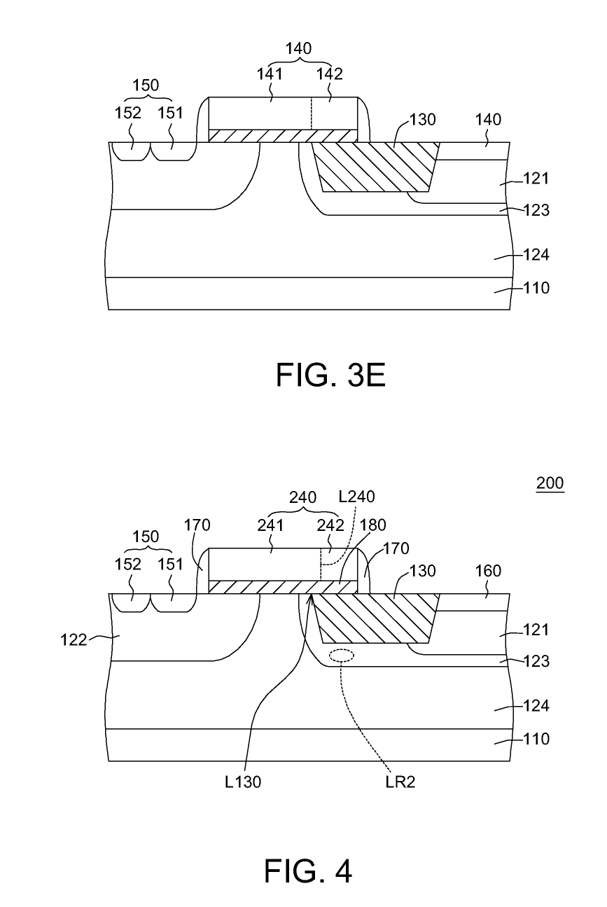

Please refer to FIG. 4, which shows a LDMOS 200 according to a second embodiment. The LDMOS 200 of the present embodiment are different from the LDMOS 100 of the first embodiment in that the location of a first gate region 241 and a gate region 242, and the similarities are not repeated here.

In FIG. 4, the first gate region 141 is partially overlapped with the STI 130, and the second gate region 242 is fully overlapped with the STI 130. A border L240 between the first gate region 241 and the second gate region 242 is located in an overlapping area between the gate 240 and the STI 130. The second gate region 242 also induces a low resistance region LR2 located below the second gate region 242. The low resistance region LR2 can lower the resistance of the current path for improving the on-resistance (Ron) of the LDMOS 200.

For a particular application, the doping concentration of the second gate region 142 can be increased and the area of the second gate region 142 can be reduced, such that the low resistance region LR2 which is smaller then the low resistance region LR1 still can lower the resistance of the current path for improving the on-resistance (Ron) of the LDMOS 200.

### Third Embodiment

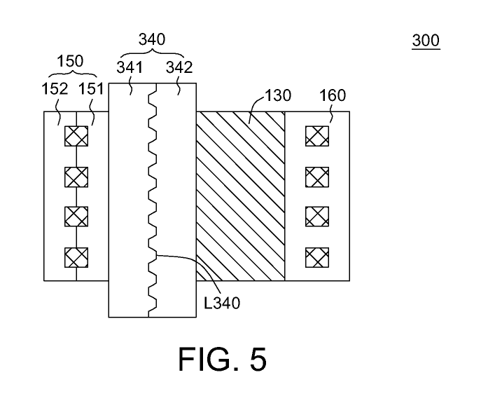

Please refer to FIG. 5, which shows a LDMOS 300 according to a third embodiment. The LDMOS 300 of the present embodiment are different from the LDMOS 100 of the first embodiment in that the shape of a border L340 between a first gate region 341 and a gate region 342, and the similarities are not repeated here.

In FIG. 5, the border L340 between the first gate region 341 and the second gate region 342 is a saw shaped line. The second gate region 342 also induces a low resistance region (not shown) located below the second gate region 342 for lowering the resistance of the current path for improving the on-resistance (Ron) of the LDMOS 300. In other embodiment, the border can be designed as varied kinds of shape for some particular applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A laterally diffused metal oxide semiconductor (LDMOS), comprising:
a substrate;
a gate disposed above the substrate, wherein the gate has a first gate region having a first dopant type and a second gate region having a second dopant type;
a first well disposed in the substrate; and
a shallow trench isolation (STI) contacted with the first well, wherein a part of the STI which contacts the first well overlaps with a projection of the gate and another part of the STI which contacts the first well is located at an outside area of the projection of the gate.

2. The LDMOS according to claim 1, wherein the second gate region is fully overlapped with the STI.

3. The LDMOS according to claim 1, wherein the first gate region is partially overlapped with the STI.

4. The LDMOS according to claim 1, wherein a border between the first gate region and the second gate region is located at an edge of the STI.

5. The LDMOS according to claim 1, wherein a border between the first gate region and the second gate region is located in an overlapping area between the gate and the STI.

6. The LDMOS according to claim 1, wherein a border between the first gate region and the second gate region is a straight line.

7. The LDMOS according to claim 1, wherein a border between the first gate region and the second gate region is a saw shaped line.

8. The LDMOS according to claim 1, further comprising:
a drain disposed in the first well, the drain having the first dopant type; and
a source having:
a first source region having the first dopant type; and
a second source region having the second dopant type.

9. The LDMOS according to claim 1, further comprising:
a second well having the second dopant type, wherein the source is disposed in the second well and the second well is spaced apart from the first well.

10. The LDMOS according to claim 1, further comprising:
a deep field having the first dopant type where the STI and the first well are disposed.

11. The LDMOS according to claim 1, wherein the first dopant type is N type, and the second dopant type is P type.

12. A manufacturing method of a laterally diffused metal oxide semiconductor (LDMOS), comprising:
providing a substrate;
forming a first well in the substrate;
forming a shallow trench isolation (STI) contacted with the first well;
forming a gate above the substrate;
forming a first gate region having a first dopant type in the gate; and
forming a second gate region having a second dopant type in the gate, wherein part of the STI which contacts the first well overlaps with a projection of the gate and another part of the STI which contacts the first well is located at an outside area of the projection of the gate.

13. The manufacturing method of the LDMOS according to claim 12, wherein in the step of forming the second gate region, the second gate region is fully overlapped with the STI.

14. The manufacturing method of the LDMOS according to claim 12, wherein in the step of forming the first gate region, the first gate region is partially overlapped with the STI.

15. The manufacturing method of the LDMOS according to claim 12, further comprising:
forming a drain having the first dopant type in the first well;
forming a first source region a source, the first source region having the first dopant type; and
forming a second source region having the second dopant type at least partially overlapped with the STI.

16. The manufacturing method of the LDMOS according to claim 15, wherein the step of forming the first gate region, the step of forming the drain and the step of forming the first source region are performed at the same time.

17. The manufacturing method of the LDMOS according to claim 15, wherein the step of forming the second gate region and the step of forming the second source region are performed at the same time.

18. The manufacturing method of the LDMOS according to claim 12, further comprising:
forming a second well having the second dopant type spaced apart from the first well.

19. The manufacturing method of the LDMOS according to claim 12, further comprising:
forming a deep field having the first dopant type where the STI and the first well are disposed.

20. The manufacturing method of the LDMOS according to claim 12, wherein the first dopant type is N type, and the second dopant type is P type.
